(19) United States
(12) Patent Application Publication
(10) Pub. No.: US 2005/0153536 A1
(43) Pub. Date: Jul. 14, 2005

(54) Method for manufacturing semiconductor device

(75) Inventor: Eiichi Soda, Kanagawa (JP)

Correspondence Address: LEYDIG VOIT & MAYER, LTD, 700 THIRTEENTH ST. NW, SUITE 300, WASHINGTON, DC, 20005-3960, US

(73) Assignee: Semiconductor Leading Edge Technologies, Inc., Tsukuba-shi (JP)

(21) Appl. No.: 11/002,246

(22) Filed: Dec. 3, 2004

(30) Foreign Application Priority Data
Jan. 13, 2004 (JP) 2004-005581

(51) Int. Cl. H01L 21/44; H01L 21/4763

(52) U.S. Cl. 438/622; 438/687; 438/623

(57) ABSTRACT

A first insulating film, a second insulating film, a third insulating film, an antireflective film, and a resist film are formed in this order on a lower-layer wiring. After dry etching the third insulating film and the second insulating film, using the resist film as a mask, the resist film and the antireflective film are removed by ashing. Thereafter, the first insulating film is dry etched, using the third insulating film as a mask, to form a wiring trench extending to the lower-layer wiring. Dry etching uses a fluorocarbon-based gas to which at least one of hydrogen and an inert gas is added. Ashing is performed using at least one of hydrogen and an inert gas.

### BACKGROUND OF THE INVENTION

1. Field of the Invention

The present invention relates to a method for manufacturing a semiconductor device, and more specifically, to a method for manufacturing a semiconductor device using a insulating film having a low relative dielectric constant as an interlayer insulating film.

2. Background Art

In recent years, the speed of semiconductor devices has markedly risen, and concurrently, transmission delay due to lowered signal transmission speed caused by the parasitic capacitance between wiring resistances and wirings in multi-layer wiring portions has caused problems. Such problems tend to be more significant with increase in the wiring resistance and the parasitic capacitance due to the reduction of wiring width and wiring distance accompanying the high integration of semiconductor devices.

Heretofore, in order to prevent the signal delay due to increase in wiring resistance and parasitic capacitance, copper wirings substituting aluminum wirings have been introduced, and the use of a insulating film having a low relative dielectric constant (hereafter referred to as “low-k film”) as an interlayer insulating film has been examined.

The methods for forming copper wiring using a low-k film include the Damascene method (e.g., refer to Japanese Patent Laid-Open No. 2002-270586). This method has been known as the technique for forming wiring without etching copper, because copper is more difficult to control the etching rate than aluminum.

Specifically, the Damascene method is a method wherein an etching-stopper film, a low-k film and a cap film are formed on a lower-layer wiring in this order, a wiring trench is formed by dry etching using a resist film as a mask, the resist film is removed by ashing, and then, a copper layer is buried in the wiring trench to form a copper wiring layer. The copper layer can be buried by forming the copper layer using a plating method so as to fill the wiring trench, and then by planarizing the surface using a CMP (chemical-mechanical polishing) method so as to leave the copper layer only in the wiring trench.

However, when the low-k film or the cap film is formed, a damaged layer may be formed on the boundary between the etching-stopper film and the low-k film, or on the boundary between the low-k film and the cap film. On the other hand, a gas containing oxygen has been conventionally used in the dry etching step and the ashing step. However, there has been a problem that a new damaged layer is formed on the sidewall of the wiring trench due to an action of oxygen and the damaged layer formed on the boundary is enlarged.

If the damaged layer formed on the boundary is enlarged, the escape of moisture or etching-gas-derived components adsorbed on the surface of the damaged layer during the heat treatment after the formation of the copper layer using a plating method causes peeling in the boundary on which the damaged layer is formed. Such peeling causes the expansion and peeling of the copper layer, resulting in the impossibility of surface planarizing treatment using a CMP method, the short-circuiting between wirings and the lowered reliability of the semiconductor device.

### SUMMARY OF THE INVENTION

The object of the present invention is to solve these problems. Specifically, the object of the present invention is to provide a method for manufacturing a semiconductor device without forming a damaged layer on the sidewall of the wiring trench, and without enlarging the damaged layer formed on the boundary in the dry etching step and the ashing step.

According to one aspect of the present invention, in a method for manufacturing a semiconductor device having a multi-layer wiring structure, a first insulating film is formed on a lower-layer wiring on a semiconductor substrate. A second insulating film having a large etching selection ratio to said first insulating film, and having a relative dielectric constant of 3.0 or below, is formed on the first insulating film. A third insulating film is formed on the second insulating film. A first resist film having a predetermined pattern is formed on the third insulating film. First dry etching is performed to the third insulating film and the second insulating film using the first resist film as a mask, to form an opening extending to the first insulating film. The first resist film is removed by first ashing. Second dry etching is performed to the first insulating film using the third insulating film as a mask, to form a wiring trench extending to the lower-layer wiring. A copper layer is formed so as to bury the wiring trench. The surface is planarized using a CMP method so as to leave the copper layer only in the wiring trench, to form a trench wiring electrically connected to the lower-layer wiring. The first dry etching and the second dry etching are performed using a fluorocarbon-based gas to which at least one of hydrogen gas and an inert gas. The first ashing is performed using at least one of hydrogen gas and an inert gas.

According to another aspect of the present invention, in a method for manufacturing a semiconductor device having a multi-layer wiring structure, a first insulating film is formed on a lower-layer wiring on a semiconductor substrate. A second insulating film having a large etching selection ratio to said first insulating film, and having a relative dielectric constant of 3.0 or below, is formed on the first insulating film. A third insulating film is formed on the second insulating film. A first antireflective film is formed on the third insulating film. A first resist film having a predetermined pattern is formed on the first antireflective film. First dry etching is performed to the first antireflective film, the third insulating film and the second insulating film using the first resist film as a mask, to form an opening extending to the first insulating film. The first resist film and the first antireflective film are removed by first ashing. Second dry etching is performed to the first insulating film using the third insulating film as a mask, to form a wiring trench extending to the lower-layer wiring. A copper layer is formed so as to bury the wiring trench. The surface is planarized using a CMP method so as to leave the copper layer only in the wiring trench, to form a trench wiring electrically connected to the lower-layer wiring. The first dry etching and the second dry etching are performed using a fluorocarbon-based gas to which at least one of hydrogen gas and an inert gas is added. The first ashing is performed using at least one of hydrogen gas and an inert gas.

Other objects and advantages of the present invention will be apparent from the following description.

### BRIEF DESCRIPTION OF THE DRAWINGS

FIG. 1 is a cross-sectional view illustrating a method for manufacturing a semiconductor device according to the present invention.

FIG. 2 is a cross-sectional view illustrating a method for manufacturing a semiconductor device according to the present invention.

FIG. 3 is a cross-sectional view illustrating a method for manufacturing a semiconductor device according to the present invention.

FIG. 4 is a cross-sectional view illustrating a method for manufacturing a semiconductor device according to the present invention.

FIG. 5 is a cross-sectional view illustrating a method for manufacturing a semiconductor device according to the present invention.

FIG. 6 is a cross-sectional view illustrating a method for manufacturing a semiconductor device according to the present invention.

FIG. 7 is a cross-sectional view illustrating a method for manufacturing a semiconductor device according to the present invention.

FIG. 8 is a cross-sectional view illustrating a method for manufacturing a semiconductor device according to the present invention.

FIG. 9 is a cross-sectional view illustrating a method for manufacturing a semiconductor device according to the present invention.

FIG. 10 is a cross-sectional view illustrating a method for manufacturing a semiconductor device according to the present invention.

FIG. 11 is a cross-sectional view illustrating a method for manufacturing a semiconductor device according to the present invention.

FIG. 12 is a cross-sectional view illustrating a method for manufacturing a semiconductor device according to the present invention.

FIGS. 13 (a) to 13 (c) are SEM photographs of a semiconductor device according to the present invention.

FIGS. 14 (a) to 14 (c) are SEM photographs of a semiconductor device according to comparative example.

### DETAILED DESCRIPTION OF THE PREFERRED EMBODIMENTS

The embodiment of the present invention will be described in detail referring to the drawings.

FIGS. 1 to 12 are sectional views illustrating the method for manufacturing a semiconductor device according to the embodiment of the present invention. In the drawings, parts denoted with the same reference numerals are the same parts.

First, a semiconductor substrate on which a lower-layer wiring 1 has been formed is prepared (FIG. 1). As the semiconductor substrate, for example, a silicon substrate can be used. For simplification, the structure of the lower-layer wiring 1 is not shown.

Next, on the lower-layer wiring 1, a first insulating film 2 and a second insulating film 3 are formed in this order (FIG. 1). Here, the first insulating film 2 and the second insulating film 3 can be formed using a plasma CVD method or a spin-coating method.

The first insulating film 2 is an etching stopper film, and is formed using a material having a large etching selection ratio to the second insulating film 3. For example, a silicon nitride (SiN) film, a silicon carbide (SiC) film, or a silicon carbonitride (SiCN) film can be used. Since these materials have low copper diffusibility, the use of these materials as the first insulating film 2 can make the first insulating film 2 function also as a diffusion preventing film.

As the second insulating film 3, a film having a relative dielectric constant lower than the relative dielectric constant of a silicon dioxide (SiO₂) film is used. Specifically, a insulating film having a low relative dielectric constant (low-k film) having a relative-dielectric constant of 3.0 or below, preferably 2.5 or below, is used. For example, materials such as organo polysiloxanes, which are polysiloxanes having organic functional groups, and a porous organic polymer containing aromatic groups can be used. Of these materials, organo polysiloxanes, such as alkyl silsesquioxane and alkyl siloxane hydride are preferably used for the excellent dielectric properties and workability thereof. The examples include materials that have siloxane bonds having methyl groups, such as methyl silsesquioxane (MSQ) and methylated hydrogen silsesquioxane (MHSQ) as the main chain-forming bonds. Of these materials, MSQ represented by Formula (1) that excels in dielectric properties and workability is preferably used, and porous MSQ having lower relative dielectric constant is more preferably used.

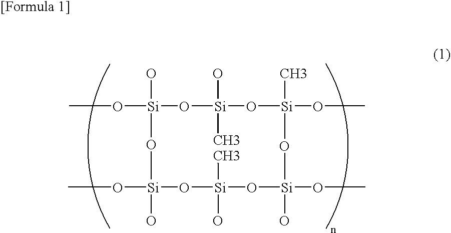

The second insulating film 3 can be formed by a plasma CVD method using, for example, a mixture gas of alkyl silane gas and an oxidizing gas as the material gas. Here, the examples of the alkyl silane gas include monomethyl silane, dimethyl silane, trimethyl silane, and tetramethyl silane. Of these silanes, trimethyl silane is most preferably used. A single alkyl silane can be used, or a combination of two or more silanes can also be used. On the other hand, as the oxidizing gas, the gas having an oxidizing function to alkyl silanes, and containing oxygen atoms in the molecule are used. For example, one or more gas selected from a group consisting of nitrogen monoxide (NO) gas, nitrogen dioxide (NO₂) gas, carbon monoxide (CO) gas, carbon dioxide (CO₂) gas, and oxygen (O₂) gas can be used. Of these gases, NO gas or NO₂ gas, which has a moderate oxidizing ability is preferably used.

The second insulating film 3 can also be formed using a spin-coating method. For example, after drop-coating the composition of the second insulating film on a wafer rotating at a predetermined rotation speed, a multi-stage heat treatment, and drying and curing are performed to form the second insulating film 3. In this case, an insulating film having a low relative dielectric constant can be formed by changing the conditions of the heat treatment to enhance the porosity of the formed film.

After forming the second insulating film 3, a third insulating film 4 is further formed thereon (FIG. 1). The third insulating film 4 is a cap film, and plays the role to prevent the plasma damage of the second insulating film 3 due to the ashing of the resist film, as well as to prevent the elevation of the relative dielectric constant of the second insulating film 3 due to moisture absorption, when the step of patterning the resist film using a photolithography method is reworked. Furthermore, the third insulating film 4 plays the role as a CMP stopper in the step of forming the copper wiring layer.

As the third insulating film 4, a silicon dioxide (SiO₂) film, a silicon carbide (SiC) film, a silicon carbonitride (SiCN) film, or a silicon nitride (SiN) film can be used. A laminated film formed by laminating two or more of these films can also be used as the third insulating film 4.

Next an antireflective film 5 as a first antireflective film is formed on the third insulating film 4. Thereafter; a resist film 6 as a first resist film having a predetermined pattern is formed on the antireflective film 5 (FIG. 1). Specifically, a photoresist (not shown) is applied onto the entire surface of the antireflective film 5, exposed through a mask having a predetermined pattern, and developed. Thereby, the photoresist can be patterned to form the resist film 6.

The antireflective film 5 plays a role to eliminate the reflection of exposing light at the boundary between the photoresist and the antireflective film 5 by absorbing the exposing light having passed through the photoresist when the photoresist is patterned. As the antireflective film 5, an organic-matter-based film can be used, and can be formed by a spin-coating method or the like. In the present invention, the antireflective film 5 is not necessarily required.

The type of the resist film 6 is adequately selected depending on the size of the formed pattern. For example, when the pattern size is 180 to 250 nm, a resist corresponding to the exposing apparatus using a krypton fluoride (KrF) excimer layer (wavelength: 248 nm) (KrF resist) as a light source can be used. When the pattern size is 100 to 130 nm, a resist corresponding to the exposing apparatus using a argon fluoride (ArF) excimer layer (wavelength: 193 nm) (ArF resist) as a light source can be used. Furthermore, when the pattern size is 50 to 70 nm, a resist corresponding to the exposing apparatus using a fluorine (F₂) layer (wavelength: 157 nm) as a light source (F₂ resist) can be used.

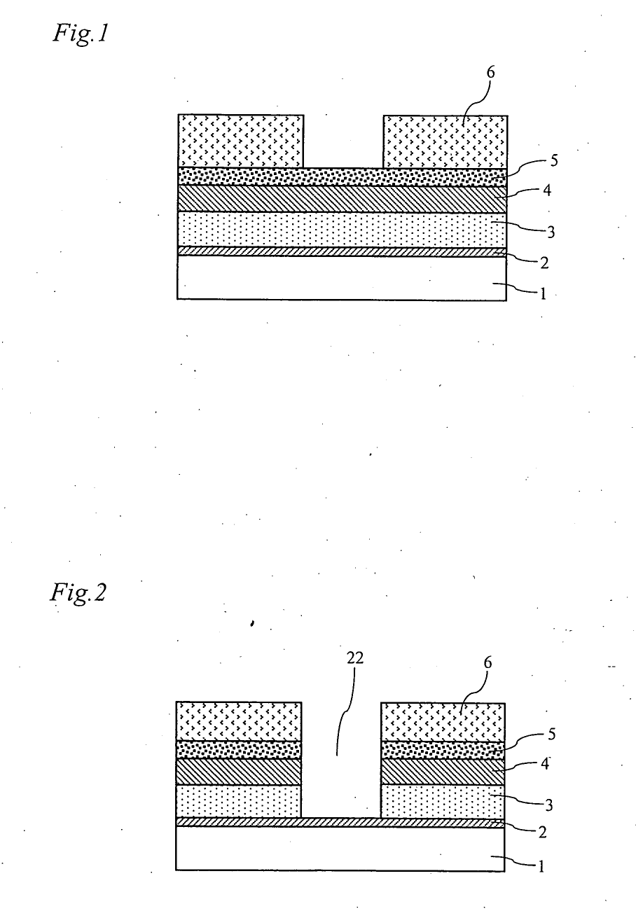

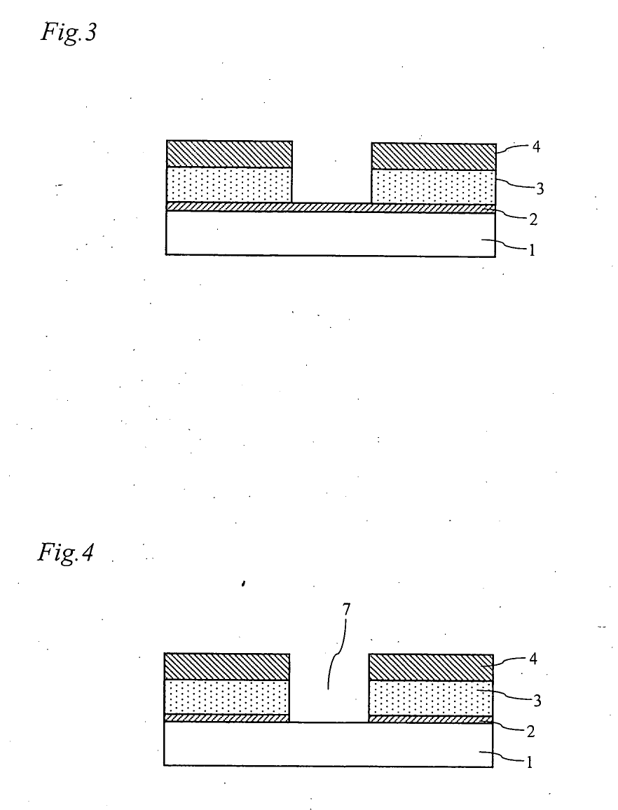

Next, using the resist film 6 as a mask, the antireflective film 5, the third insulating film 4 and the second insulating film 3 are subjected to dry etching (first dry etching). This etching is automatically terminated when the first insulating film 2 is reached, and an opening 22 extending to the first insulating film 2 is formed (FIG. 2). Thereafter, the resist film 6 and the antireflective film 5 no longer required are removed using ashing (first ashing) (FIG. 3), and then, the first insulating film 2 is subjected to dry etching (second dry etching) using the third insulating film 4 as a mask (FIG. 4). At this time, over etching is performed so that the first insulating film 2 does not remain and the lower-layer wiring 1 is completely exposed on the surface.

The present invention is characterized in that a gas containing no oxygen (O₂) is used in the first dry etching step and the second dry etching step.

Specifically, the first dry etching step can be carried out using a fluorocarbon-based gas to which hydrogen (H₂) gas is added. The first dry etching step can also be carried out using a fluorocarbon-based gas to which one or more inert gas, such as nitrogen (N₂), helium (He), neon (Ne) and argon (Ar), is added. Furthermore, the first dry etching step can also be carried out using a fluorocarbon-based gas to which H₂ gas and one or more inert gas is added. The examples of fluorocarbon-based gases include tetrafluoromethane (CF₄), octafluorocyclobutane (C₄F₈), octafluorocyclopentene (C₅F₈), hexafluoroethane (C₂F₆), hexafluorobutadiene (C₄F₆), and hexafluorobenzene (C₆F₆). The same applies to the second dry etching. However, the gas used in the second dry etching must have the different composition from the gas used in the first dry etching.

On the other hand, the first ashing can be performed using H₂ gas, or can be performed using one or more inert gas, such as N₂, He, Ne and Ar. Furthermore, the first ashing can be performed using H₂ gas to which one or more inert gas is mixed.

Here, if a gas containing oxygen is used in the first dry etching, the first ashing and the second dry etching, a damaged layer is formed on the sidewall of the second insulating film 3 due to the reaction of the second insulating film 3 with oxygen. If the damaged layer is formed in the boundary between the first insulating film 2 and the second insulating film 3 and/or the boundary between the second insulating film 3 and the third insulating film 4 during layer formation, the damaged layer is enlarged due to the action of oxygen. According to the present invention, however, since the dry etching and ashing are performed using a gas containing no oxygen, no damaged layer is formed on the sidewall of the second insulating film 3. In addition, the damaged layer formed in the boundary of the second insulating film 3 is not enlarged.

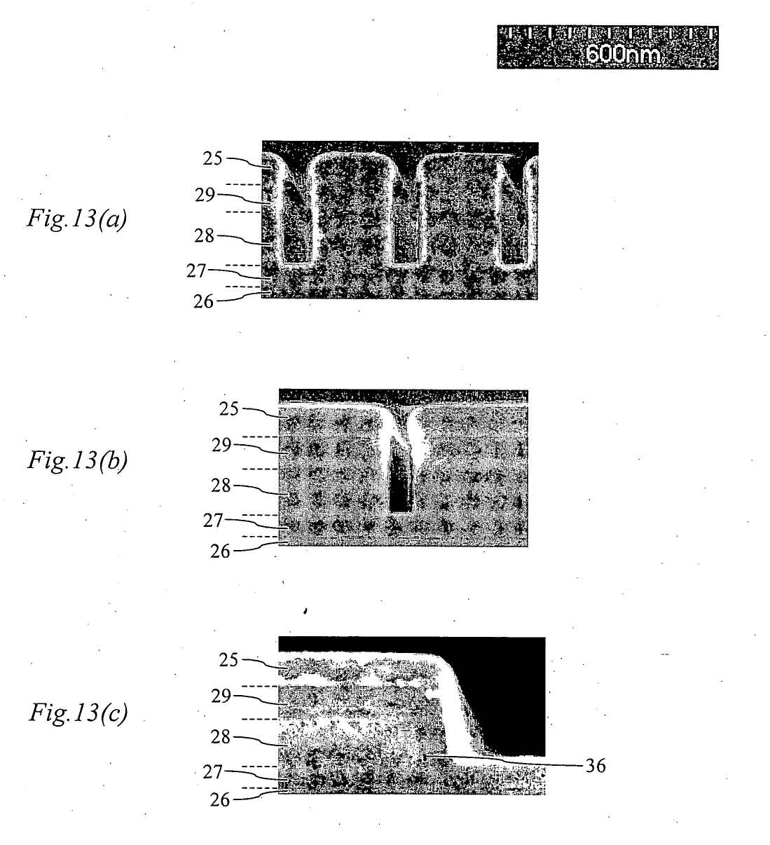

FIG. 13 is SEM (scanning electron microscope) photographs of a semiconductor device, wherein the SiC film 25 of a thickness of 100 nm is formed after the first ashing using a mixture gas of H₂ gas and He gas and then treated with a hydrofluoric acid (HF) solution. In this example, an SiC film 27 as the first insulating film, a porous MSQ film (relative dielectric constant: 2.3) 28 as the second insulating film, and an SiO₂ film 29 as the third insulating film are laminated in this order on a silicon substrate 26. Ashing is performed under the conditions of the flow rate of the H₂ gas of 500 sccm, the flow rate of the He gas of 6500 sccm, the pressure of 100 Pa, the source power of 1000 W, the temperature of 350° C., and the ashing time of 120 seconds.

FIG. 13 shows three examples ((a) to (c)) of different pattern line width and different distance between patterns. Although the distance between patterns in FIGS. 13 (a) and 13 (b) is substantially the same, the pattern line width in FIG. 13 (b) is larger than that in FIG. 13 (a). Both the distance between patterns and the pattern line width in FIG. 13 (c) is larger than those in FIG. 13 (a).

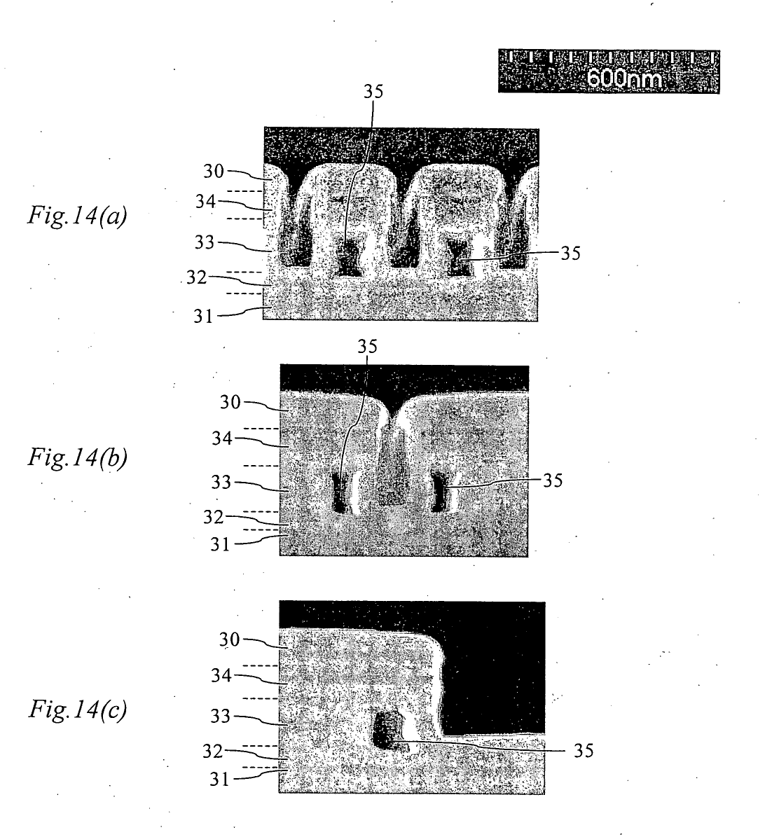

FIG. 14 shows comparative examples of the examples shown in FIG. 13, and is SEM (scanning electron microscope) photographs of a semiconductor device, wherein the SiC film 30 of a thickness of 100 nm is formed after ashing using O₂ gas and then treated with a hydrofluoric acid (HF) solution. Similar to the examples shown in FIG. 13, an SiC film 32 as the first insulating film, a porous MSQ film (relative dielectric constant: 2.3) 33 as the second insulating film, and an SiO₂ film 34 as the third insulating film are laminated in this order on a silicon substrate 31. Ashing is performed under the conditions of the flow rate of the O₂ gas of 200 sccm, the pressure of 35 Pa, the source power of 4000 W, the bias power of 150 W, the temperature of 25° C., and the ashing time of 30 seconds.

Similar to FIG. 13, FIG. 14 shows three examples ((a) to (c)) of different pattern line width and different distance between patterns. Although the distance between patterns in FIGS. 14 (a) and 14 (b) is substantially the same, the pattern line width in FIG. 14 (b) is larger than that in FIG. 14 (a). Both the distance between patterns and the pattern line width in FIG. 14 (c) is larger than those in FIG. 14 (a).

As seen from FIGS. 14 (a) to 14 (c), the ashing using O₂ gas forms voids 35 as a result of dissolution of the damaged layers formed in the porous MSQ film 33 in the HF solution. On the other hand, in the example of FIG. 13, although an extremely small void 36 formed on the sidewall of the porous MSQ film 28 can be observed in FIG. 13 (c), no voids are observed in FIGS. 13 (a) and 13 (b). Therefore, it is seen that ashing using a mixture gas of H₂ gas and He gas can significantly reduce damage to the porous MSQ film.

For example, when an SiC film is used as the first insulating film 2, a porous MSQ film is used as the second insulating film 3, and an SiO₂ film is used as the third insulating film 4, Ar gas and N₂ gas can be added to a fluorocarbon-based gas to perform the first dry etching to the SiO₂ film and the porous MSQ film. Similarly, Ar gas can be added to a fluorocarbon-based gas to perform the second dry etching to the SiC film. On the other hand, if an ArF resist is used for the resist film 6, a mixture gas of N₂ gas and H₂ gas can be used to perform the first ashing of the ArF resist.

After the completion of the second dry etching, a cleaning treatment is performed on the surface of the semiconductor substrate to remove the residual resist and the like. Through the above steps, as FIG. 4 shows, a wiring trench 7 extending to the lower-layer wiring 1 is formed.

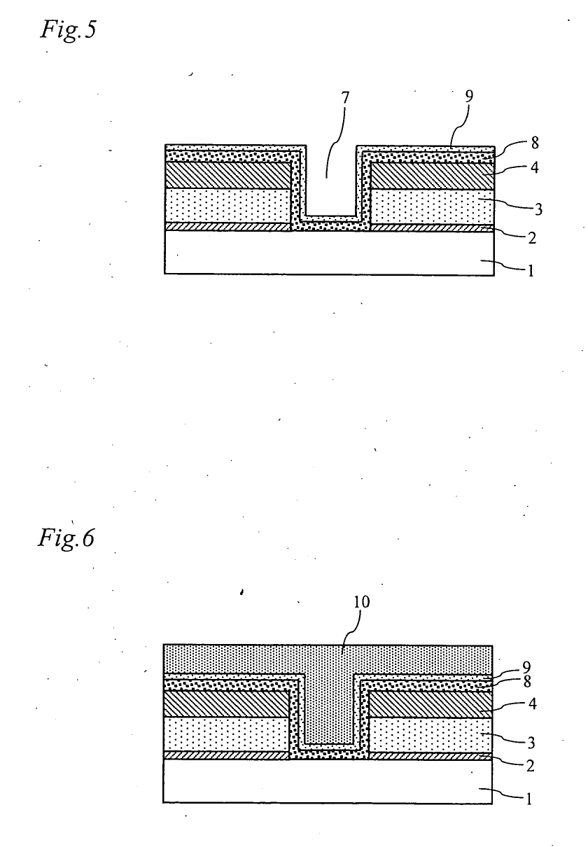

Next, after forming a barrier metal film 8 on the entire surface including the wiring trench 7, a seed copper (Cu) film 9 is formed (FIG. 5). These films can be formed using a sputtering method.

The barrier metal film 8 can be formed using a tantalum (Ta) film, a tantalum nitride (TaN) film, a tungsten (W) film, a tungsten nitride (WN) film, a titanium (Ti) film or a titanium nitride (TiN) film.

After the seed copper film 9 is formed, a copper layer 10 is formed using a plating method (FIG. 6). Here, although the copper layer 10 may be a layer consisting only of copper, it may be a layer consisting of an alloy of copper with other metals. Specifically, an alloy containing 80% or more, preferably 90% by weight of copper, and other metals, such as magnesium (Mg), scandium (Sc), zirconium (Zr), hafnium (Hf), niobium (Nb), tantalum (Ta), chromium (Cr) and molybdenum (Mo), can be used. If such copper alloys are used for the wiring layer, the electrical reliability of the semiconductor device can be improved.

After the copper layer 10 is formed, heat treatment is performed to grow copper grains, and to evenly fill the wiring trench 7 with copper. According to the present invention, since gases containing oxygen are not used in the dry etching step and the ashing step, no damage layer is formed on the sidewall of the second insulating film 3. Therefore, no moisture or etching-gas-derived components escape from the surface of the damaged layer when heat treatment is performed. Therefore, according to the present invention, the copper layer 10 is not peeled off or expanded.

After the heat treatment is completed, the surface is planarized using a CMP method, and the copper layer 10, the seed copper film 9, and the barrier metal film 8 are removed except those in the wiring trench 7. At this time, since the third insulating film 4 functions as a CMP stopper, polishing is automatically stopped when the third insulating film 4 is exposed.

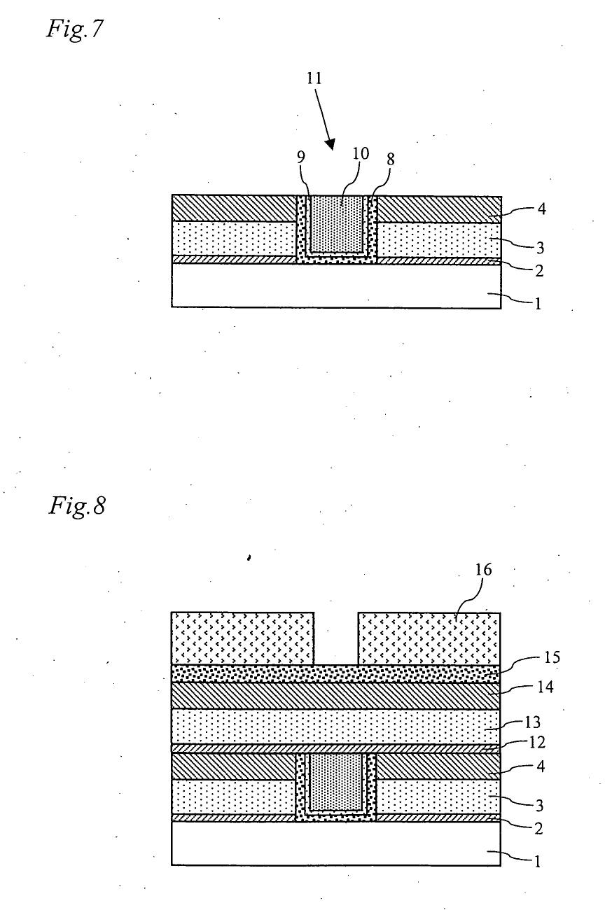

Through the above steps, a trench wiring 11 electrically connected to the lower-layer wiring 1 can be formed (FIG. 7).

Next, the steps of forming a via plug electrically connected to the trench wiring 11 will be described.

First, a fourth insulating film 12 is formed on the trench wiring 11 (FIG. 8). The fourth insulating film 12 is an etching stopper film similar to the first insulating film 2 as well as a diffusion preventing film, and plays a role to prevent the diffusion of copper into the fifth insulating film 13 formed in the subsequent step. As the fourth insulating film 12, for example, a silicon carbide (SiC) film, a silicon carbonitride (SiCN) film, or a silicon nitride (SiN) film can be used, and these can be formed using a plasma CVD method or the like.

Next, a fifth insulating film 13 and a sixth insulating film 14 are formed on the fourth insulating film 12. On the sixth insulating film 14, an antireflective film 15 is formed as a second resist film, and then, on the antireflective film 15, a resist film 16 is formed as a second resist film (FIG. 8). Here, as the antireflective film 15 and the resist film 16, the films similar to the antireflective film 5 and the resist film 6 used in the formation of the wiring trench 11 can be used.

As the fifth insulating film 13, a film similar to the second insulating film 3 can be used. Specifically, a insulating film having a low relative dielectric constant (low-k film) having a large etching selection ratio to the fourth insulating film 12, and a relative dielectric constant of 3.0 or below, preferably 2.5 or below, is used as the fifth insulating film 13. For example, materials such as organo polysiloxanes, which are polysiloxanes having organic functional groups, and a porous organic resin containing aromatic groups can be used. Of these materials, organo polysiloxanes, such as alkyl silsesquioxane and alkyl siloxane hydride are preferably used for the excellent dielectric properties and workability thereof. The examples include materials that have siloxane bonds having methyl groups, such as methyl silsesquioxane (MSQ) and methylated hydrogen silsesquioxane (MHSQ) as the main chain-forming bonds. Of these materials, MSQ represented by Formula (1) that excels in dielectric properties and workability is preferably used, and porous MSQ having lower relative dielectric constant is more preferably used.

The sixth insulating film 14 is a cap film, and a film similar to the third insulating film 4 can be used as the sixth insulating film 16.

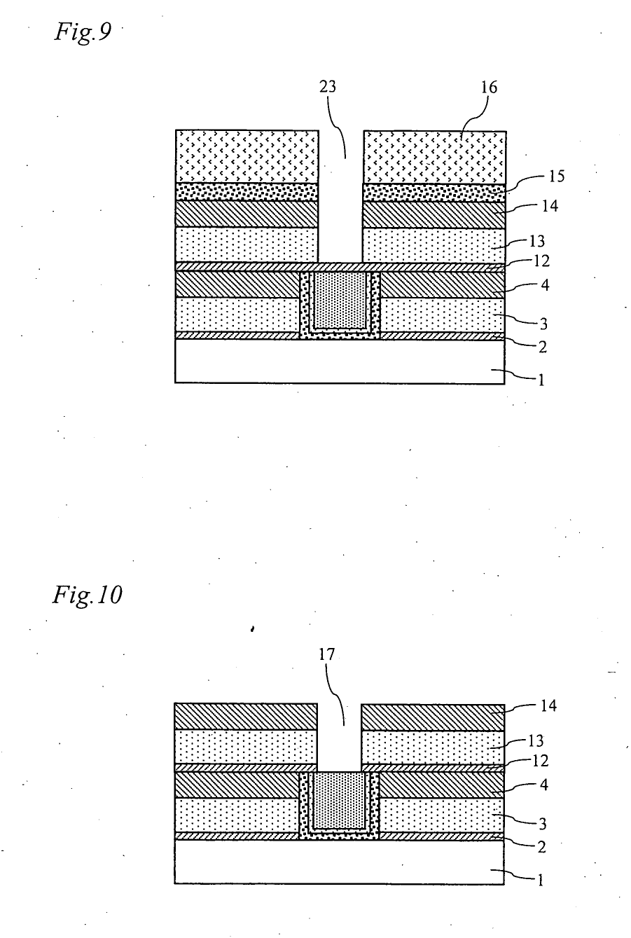

Next, using the resist film 16 as a mask, the antireflective film 15, the sixth insulating film 14 and the fifth insulating film 13 are subjected to dry etching (third dry etching). Thereby, an opening 23 extending to the fourth insulating film 12 is formed (FIG. 9). Thereafter, the resist film 16 and the antireflective film 15 no longer required are removed using ashing (second ashing), and then, the fourth insulating film 12 is subjected to dry etching (fourth dry etching) using the sixth insulating film 14 as a mask. Thereby, a via hole 17 extending to the trench wiring 11 can be formed (FIG. 10).

In the present invention, a gas containing no oxygen is used in the third dry etching step, the second ashing step, and the fourth dry etching step, as in the formation of the wiring trench 7.

Specifically, the third dry etching step can be carried out using a fluorocarbon-based gas to which hydrogen (H₂) gas, or one or more inert gas, such as nitrogen (N₂), helium (He), neon (Ne) and argon (Ar), is added. Furthermore, the third dry etching step can also be carried out using a fluorocarbon-based gas to which H₂ gas and one or more inert gas is added. The examples of fluorocarbon-based gases include tetrafluoromethane (CF₄), octafluorocyclobutane (C₄F₈), octafluorocyclopentene (C₅F₈), hexafluoroethane (C₂F₆), hexafluorobutadiene (C₄F₆), and hexafluorobenzene (C₆F₆).

The fourth dry etching is similar to the third dry etching. However, the gas used in the fourth dry etching must have the different composition from the gas used in the third dry etching.

On the other hand, the second ashing can be-performed using H₂ gas, or can be performed using one or more inert gas, such as N₂, He, Ne and Ar. Furthermore, the second ashing can be performed using H₂ gas to which one or more inert gas is mixed.

According to the present invention, since the third dry etching, the second ashing, and the fourth dry etching are performed using a gas containing no oxygen, no damaged layer is formed on the sidewall of the fifth insulating film 13. In addition, even if the damaged layer is formed in the boundary of the fourth insulating film 12 and the fifth insulating film 13 and/or the boundary of the fifth insulating film 13 and the sixth insulating film 14, the damaged layer is not enlarged by dry etching and ashing.

For example, when an SiC film is used as the fourth insulating film 12, a porous MSQ film is used as the fifth insulating film 13, and an SiO₂ film is used as the sixth insulating film 14, Ar gas and N₂ gas can be added to a fluorocarbon-based gas to perform the third dry etching to the SiO₂ film and the porous MSQ film. Similarly, Ar gas can be added to a fluorocarbon-based gas to perform the fourth dry etching to the SiC film. On the other hand, if an ArF resist is used for the resist film 16, a mixture gas of N₂ gas and H₂ gas can be used to perform the second ashing of the ArF resist.

After the formation of the via hole 17, a cleaning treatment is performed on the surface of the semiconductor substrate to remove the residual resist and the like.

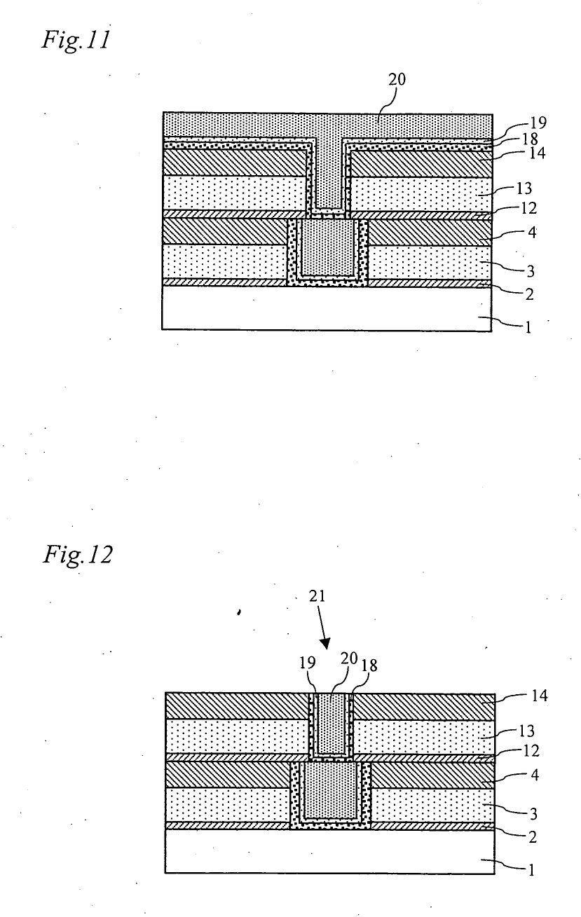

Next, in the same manner as in the formation of the trench wiring 11, a barrier metal film 18 and a seed copper (Cu) film 19 are formed on the entire surface including the via hole 17, and then, a copper layer 20 is formed using a plating method (FIG. 11). Thereafter, heat treatment is performed to grow copper grains, and to evenly fill the via hole 17 with copper. According to the present invention, since gases containing oxygen are not used in the dry etching step and the ashing step, no damage layer is formed on the sidewall of the fifth insulating film 13. Therefore, no moisture or etching-gas-derived components escape from the surface of the damaged layer when heat treatment is performed. According to the present invention, therefore, the copper layer 20 is not peeled off or expanded.

After the heat treatment is completed, the surface is planarized using a CMP method, and the copper layer 20, the seed copper film 19, and the barrier metal film 18 are removed except those in the via hole 17. At this time, since the sixth insulating film 14 functions as a CMP stopper, polishing is automatically stopped when the sixth insulating film 14 is exposed.

Through the above steps, a via plug 21 electrically connected to the trench wiring 11 can be formed (FIG. 12).

By repeating the above-described steps of forming the trench wiring and the via plug, a multi-layer copper wiring structure without the peeling of the copper layer can be obtained. Therefore, according to the present invention, a semiconductor device of high reliability can be manufactured.

The etching apparatus used in the embodiment may be of either a dual-frequency RIE (reactive ion etching) type, or an ICP (inductivity coupled plasma) type. The ashing apparatus may be a down-flow-type surface wave plasma asher or an ICP-type plasma asher. The above-described etching apparatus can also be used as an ashing apparatus.

In this embodiment, although an example of the single Damascene process is described, the present invention is not limited thereto. The present invention can be equally applied to the dry etching process and the ashing process in the dual Damascene process.

The features and advantages of the present invention may be summarized as follows.

According to the present invention, since dry etching is performed using a fluorocarbon-based gas to which at least one of hydrogen gas or an inert gas is added, and ashing is performed using at least one of hydrogen gas or an inert gas, the formation of a damaged layer on the sidewall of a insulating film having a low relative dielectric constant can be prevented. Even if damaged layers are formed in the boundaries between the insulating film having a low relative dielectric constant and other films, the expansion of the damage layers can be prevented.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2004-005581, filed on Jan. 13, 2004 including specification, claims, drawings and summary, on which the Convention priority of the present application is based, are incorporated herein by reference in its entirety.

1. A method of manufacturing a semiconductor device having a multi-layer wiring structure, comprising:
forming a first insulating film on a lower-layer wiring that is on a semiconductor substrate;
forming a second insulating film having a large etching selection ratio relative to said first insulating film, and having a relative dielectric constant not exceeding 3.0, on said first insulating film;
forming a third insulating film on said second insulating film;
forming a first resist film having a predetermined pattern on said third insulating film;
dry etching said third insulating film and said second insulating film, using said first resist film as a mask, to form an opening extending to said first insulating film;
removing said first resist film by ashing;
dry etching said first insulating film, using said third insulating film as a mask, to form a wiring trench extending to said lower-layer wiring;
forming a copper layer filling said wiring trench; and
planarizing by chemical mechanical polishing CMP, leaving said copper layer only in said wiring trench, to form trench wiring electrically connected to said lower-layer wiring, wherein
dry etching of said third and second insulating films and dry etching of said first insulating film uses a fluorocarbon-based gas to which at least one of hydrogen and an inert gas is added; and
ashing uses at least one of hydrogen and an inert gas.

2. The method of manufacturing a semiconductor device according to claim 1, further comprising:
forming a fourth insulating film on said trench wiring;
forming a fifth insulating film having a large etching selection ratio relative to said fourth insulating film, and having a relative dielectric constant not exceeding 3.0, on said fourth insulating film;
forming a sixth insulating film on said fifth insulating film;
forming a second resist film having a predetermined pattern on said sixth insulating film;
dry etching said sixth insulating film and said fifth insulating film, using said second resist film as a mask, to form an opening extending to said fourth insulating film;
removing said second resist film by ashing;
dry etching said fourth insulating film, using said sixth insulating film as a mask, to form a via hole extending to said trench wiring;
forming a copper layer filling said via hole; and
planarizing by CMP, leaving said copper layer only in said via hole, to form a via plug electrically connected to said trench wiring, wherein
dry etching of said sixth and fifth insulating films and dry etching of said fourth insulating film uses a fluorocarbon-based gas to which at least one of hydrogen and an inert gas is added; and
ashing said second resist film uses at least one of hydrogen and an inert gas.

3. The method of manufacturing a semiconductor device according to claim 1, wherein said inert gas is at least one gas selected from the group consisting of nitrogen, helium, neon, and argon.

4. The method of manufacturing a semiconductor device according to claim 1, wherein said second insulating film is composed of a material that has siloxane bonds having methyl group as chain-forming bonds.

5. The method of manufacturing a semiconductor device according to claim 4, wherein said second insulating film is one of a methyl silsesquioxane (MSQ) film and a porous MSQ film.

6. The method of manufacturing a semiconductor device according to claim 1, wherein said fifth insulating film is composed of a material that has siloxane bonds having methyl groups as chain-forming bonds.

7. The method of manufacturing a semiconductor device according to claim 6, wherein said fifth insulating film is one of a methyl silsesquioxane (MSQ) film and a porous MSQ film.

8. The method of manufacturing a semiconductor device according to claim 1, wherein said first insulating film is selected from the group consisting of silicon nitride, silicon carbide, and silicon carbonitride.

9. The method of manufacturing a semiconductor device according to claim 1, wherein said fourth insulating film is selected from the group consisting of silicon nitride, silicon carbide, and silicon carbonitride.

10. The method of manufacturing a semiconductor device according to claim 1, wherein said third insulating film is one of a single-layer film selected from the group consisting of silicon dioxide, silicon carbide, silicon carbonitride, and silicon nitride, or a laminated film composed of at least two films.

11. The method of manufacturing a semiconductor device according to claim 1, wherein said sixth insulating film is a single-layer film selected from the group consisting of silicon dioxide, silicon carbide, silicon carbonitride, and silicon nitride, or laminated film composed of at least two films.

12. A method of manufacturing a semiconductor device having a multi-layer wiring structure, comprising:
forming a first insulating film on a lower-layer wiring that is on a semiconductor substrate;
forming a second insulating film having a large etching selection ratio relative to said first insulating film, and having a relative dielectric constant not exceeding 3.0, on said first insulating film;
forming a third insulating film on said second insulating film;
forming a first antireflective film on said third insulating film;
forming a first resist film having a predetermined pattern on said first antireflective film;
dry etching said first antireflective film, said third insulating film, and said second insulating film, using said first resist film as a mask, to form an opening extending to said first insulating film;
removing said first resist film and said first antireflective film by ashing;
dry etching said first insulating film, using said third insulating film as a mask, to form a wiring trench extending to said lower-layer wiring;
forming a copper layer filling said wiring trench; and
planarizing by chemical mechanical polishing (CMP), leaving said copper layer only in said wiring trench, to form trench wiring electrically connected to said lower-layer wiring, wherein
dry etching of said first antireflective film and said third and second insulating films and dry etching of said first insulating film uses a fluorocarbon-based gas to which at least one of hydrogen and an inert gas is added; and
ashing uses at least one of hydrogen and an inert gas.

13. The method of manufacturing a semiconductor device according to claim 12, further comprising:
forming a fourth insulating film on said trench wiring;
forming a fifth insulating film having a large etching selection ratio relative to said fourth insulating film, and having a relative dielectric constant not exceeding 3.0, on said fourth insulating film;
forming a sixth insulating film on said fifth insulating film;
forming a second antireflective film on said sixth insulating film;
forming a second resist film having a predetermined pattern on said second antireflective film;
dry etching said second antireflective film, said sixth insulating film, and said fifth insulating film, using said second resist film as a mask, to form an opening extending to said fourth insulating film;
removing said second resist film and said second antireflective film by ashing;
dry etching said fourth insulating film, using said sixth insulating film as a mask, to form a via hole extending to said trench wiring;
forming a copper layer filling said via hole; and
planarizing by CMP method, leaving said copper layer only in said via hole, to form a via plug electrically connected to said trench wiring, wherein
dry etching of said second antireflective film and said sixth and fifth insulating layers and dry etching of said fourth insulating film uses a fluorocarbon-based gas to which at least one of hydrogen and an inert gas is added; and
ashing said second resist film and said second antireflective film uses at least one of hydrogen and an inert gas.

14. The method of manufacturing a semiconductor device according to claim 12, wherein said inert gas is at least one gas selected from the group consisting of nitrogen, helium, neon, and argon.

15. The method of manufacturing a semiconductor device according to claim 12, wherein said second insulating film is composed of a material that has siloxane bonds having methyl groups as chain-forming bonds.

16. The method for manufacturing a semiconductor device according to claim 12, wherein said fifth insulating film is composed of a material that has siloxane bonds having methyl groups as chain-forming bonds.

17. The method for manufacturing a semiconductor device according to claim 12, wherein said first insulating film is selected from the group consisting of silicon nitride, silicon carbide and silicon carbonitride.

18. The method for manufacturing a semiconductor device according to claim 12, wherein said fourth insulating film is selected from the group consisting of silicon nitride, a silicon carbide, and silicon carbonitride.

19. The method for manufacturing a semiconductor device according to claim 12, wherein said third insulating film is one of a single-layer film selected from the group consisting of silicon dioxide, silicon carbide, silicon carbonitride, and silicon nitride, or a laminated film composed of at least two films.

20. The method for manufacturing a semiconductor device according to claim 12, wherein said sixth insulating film is one of a single-layer film selected from the group consisting of silicon dioxide, silicon carbide, silicon carbonitride, and silicon nitride, or a laminated film composed of at least two films.
